(19) United States
(12) Patent Application Publication
(10) Pub. No.: US 2020/0303639 A1
(43) Pub. Date: Sep. 24, 2020

(54) MEMORY DEVICE AND METHOD OF FORMING THE SAME

(71) Applicant: AGENCY FOR SCIENCE, TECHNOLOGY AND RESEARCH, Singapore (SG)

(72) Inventors: Wei HE, Singapore (SG); Franck Gerard ERNULT, Singapore (SG); Eng Keong CHUA, Singapore (SG); Yu JIANG, Singapore (SG)

(21) Appl. No.: 16/085,555

(22) PCT Filed: Mar. 14, 2017
(86) PCT No.: PCT/SG2017/050125

§ 371 Date: Sep. 14, 2018

(30) Foreign Application Priority Data
Mar. 15, 2016 (SG) 10201601973Q

(51) Int. Cl. H01L 45/00; H01L 27/24

(52) U.S. Cl. CPC H01L 45/1226; H01L 45/08; H01L 45/06; H01L 27/2427; H01L 45/146; H01L 27/249; H01L 45/1253; H01L 45/144; H01L 45/1608

(57) ABSTRACT

Embodiments provide a memory device, including a plurality of insulating layers and a plurality of lateral layer arrangements. The lateral layer arrangements and the insulating layers are arranged alternately on each other such that each lateral layer arrangement is sandwiched between neighboring insulating layers. Each lateral layer arrangement includes a first electrode layer, a second electrode layer, and a memory layer sandwiched between the first electrode layer and the second electrode layer. The memory layer and the second electrode layer are arranged at a lateral side of the first electrode layer. The memory device further include a selecting film arranged at a lateral side of the insulating layers and the lateral layer arrangements and extending in a direction at least substantially perpendicular to a lateral direction of the lateral layer arrangements, wherein the selecting film has a first surface in contact with the second electrode layer of each lateral layer The memory device further include a third electrode layer arranged in contact with a second surface of the selecting film, the second surface being opposite to the first surface.

### CROSS-REFERENCE TO RELATED APPLICATIONS

The present application claims the benefit of the Singapore patent application No. 10201601973Q filed on 15 Mar. 2016, the entire contents of which are incorporated herein by reference for all purposes.

### TECHNICAL FIELD

Embodiments relate generally to memory devices, and in particular, relate to a memory device and a method of forming a memory device.

### BACKGROUND

In recent decades, emerging nonvolatile memories including ferroelectric random access memory (FRAM), magnetic random access memory (MRAM), phase-change random access memory (PRAM), and resistive random access memory (ReRAM or RRAM) have been intensively studied. Among them, ReRAM which exhibits resistive change under external voltages, holds the advantages in its simple structure, easy fabrication, good scalability, potential high integration density, and good compatibility to the current CMOS technology.

In order to compete with current flash memory, fabrication in three-dimensional (3D) architecture of ReRAM is necessary. In the 3D architecture, current sneak path may lead to read error and high power dissipation during SET or RESET operation of the ReRAM. Besides development of ReRAM memory cells, the selector for selecting memory cells is the other critical element that may help to block the sneak current leakage path to reduce the power consumption as well as the operation error. The integration of selectors into 3D structure is thus critical in reducing power consumption and operation error.

In the existing 3D memory architecture with integration of selectors, sneak paths still exist. Accordingly, it is desired to provide high performance memory device structures to further lower the sneak current.

### SUMMARY

Various embodiments provide a memory device, including a plurality of insulating layers and a plurality of lateral layer arrangements. The lateral layer arrangements and the insulating layers are arranged alternately on each other such that each lateral layer arrangement is sandwiched between neighboring insulating layers. Each lateral layer arrangement includes a first electrode layer, a second electrode layer, and a memory layer sandwiched between the first electrode layer and the second electrode layer. The memory layer and the second electrode layer are arranged at a lateral side of the first electrode layer. The memory device further include a selecting film arranged at a lateral side of the insulating layers and the lateral layer arrangements and extending in a direction at least substantially perpendicular to a lateral direction of the lateral layer arrangements, wherein the selecting film has a first surface in contact with the second electrode layer of each lateral layer arrangement. The memory device further include a third electrode layer arranged in contact with a second surface of the selecting film, the second surface being opposite to the first surface.

Various embodiments provide a method of forming a memory device. The method may include forming a plurality of insulating layers; forming a plurality of lateral layer arrangements, wherein the lateral layer arrangements and the insulating layers are arranged alternately on each other such that each lateral layer arrangement is sandwiched between neighboring insulating layers. Each lateral layer arrangement may include a first electrode layer; a second electrode layer; and a memory layer sandwiched between the first electrode layer and the second electrode layer, wherein the memory layer and the second electrode layer are arranged at a lateral side of the first electrode layer. The method may further include forming a selecting film at a lateral side of the insulating layers and the lateral layer arrangements. The selecting film is extending in a direction at least substantially perpendicular to a lateral direction of the lateral layer arrangements, and the selecting film has a first surface in contact with the second electrode layer of each lateral layer arrangement. The method may further include forming a third electrode layer in contact with a second surface of the selecting film, the second surface being opposite to the first surface.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1 shows a cross-sectional view of a memory device according to various embodiments.

FIG. 2 shows a cross-sectional view of a memory device according to various embodiments.

FIG. 3 shows a flowchart illustrating a method of forming a memory device according to various embodiments.

FIG. 4-FIG. 13 show a process of forming a memory device according to various embodiments.

FIG. 14A-FIG. 14H show a process of forming a memory device in 3D view according to various embodiments.

FIG. 15(a) shows an equivalent circuit illustrating leakage current calculation for a memory device according to various embodiments, and FIG. 15(b) shows an equivalent circuit when reading a memory cell according to various embodiments.

FIG. 16 shows a current-voltage curve for a selector according to various embodiments.

FIG. 17 shows a diagram illustrating a leakage current percentage of a memory device according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized, and structural and logical changes may be made without departing from the scope of the invention. The various embodiments are not necessarily mutually exclusive, as some embodiments can be combined with one or more other embodiments to form new embodiments.

Various embodiments provide a 3D (three-dimensional) stacked memory architecture with self-aligned two-terminal selectors for a memory device, which reduces leakage current and leverages fabrication costs.

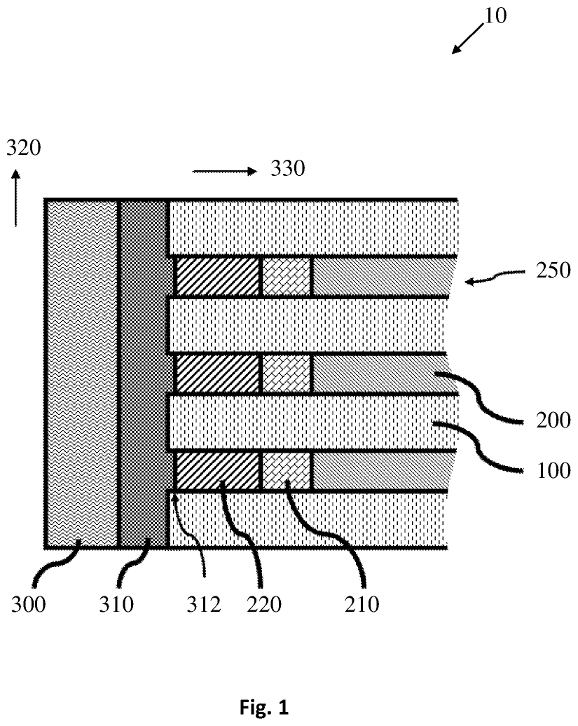

FIG. 1 shows a cross-sectional view of a memory device 10 according to various embodiments.

The memory device 10 includes a plurality of insulating layers 100 and a plurality of lateral layer arrangements 250. The lateral layer arrangements 250 and the insulating layers 100 are arranged alternately on each other such that each lateral layer arrangement 250 is sandwiched between neighboring insulating layers 100. Each lateral layer arrangement 250 includes a first electrode layer 200, a second electrode layer 220, and a memory layer 210 sandwiched between the first electrode layer 200 and the second electrode layer 220. The memory layer 210 and the second electrode layer 220 are arranged at a lateral side of the first electrode layer 200, e.g. at the left side of the first electrode layer 200 as shown in FIG. 1. In other words, the first electrode layer 200, the memory layer 210, and the second electrode layer 220 are laterally arranged with respect to each other, i.e. arranged side by side such that each of the first electrode layer 200, the memory layer 210, and the second electrode layer 220 is sandwiched between and is in contact with two neighboring insulating layers 100.

The memory device 10 further includes a selecting film 310 arranged at a lateral side of the insulating layers 100 and the lateral layer arrangements 250, e.g. at the left side of the insulating layers 100 and the lateral layer arrangements 250 in an example shown in FIG. 1. The selecting film 310 is extending in a direction 320 at least substantially perpendicular to a lateral direction 330 of the lateral layer arrangements 250. The selecting film 310 has a first surface in contact with the second electrode layer 220 of each lateral layer arrangement 250. The memory device 10 further includes a third electrode layer 300 arranged in contact with a second surface of the selecting film 310, wherein the second surface is opposite to the first surface.

According to various embodiments, the insulating layers 100 may include an insulating material, such as silicon dioxide, silicon nitride or other dielectrics.

According to various embodiments, the first electrode layer 200 of each lateral layer arrangement 250 may form a wordline of the memory device 10. The wordline 200 lays in a horizontal direction and is connected to a wordline transistor. The first electrode layer 200 may include various conductive materials, such as metals (e.g. Ta, Ti, W, Pt, Ir, Ru, Ag, Cu, TiN, TaN, etc.), conductive oxide (e.g. ITO, Fe₃O₄, etc.), or polysilicon.

According to various embodiments, the third electrode layer 300 may form a bitline of the memory device 10. The bitline runs in a vertical direction perpendicular to the wordline 200 as well as a wafer substrate supporting the memory device 10. The third electrode layer 300 may include various conductive materials, including different metals, polysilicon, or conductive oxide, etc.

In other embodiments, the first electrode layer 200 of each lateral layer arrangement 250 may form a bitline, and the third electrode layer 300 may form a wordline of the memory device 10.

According to various embodiments, the first electrode layer 200, the memory layer 210 and the second electrode layer 220 of each lateral layer arrangement 250 form a memory cell.

In various embodiments, the memory cell may include at least one of an ion-conducting based resistive random access memory (ReRAM), an anion-conducting based resistive random access memory, or a phase change random access memory (PCRAM).

The memory layer 210 represents the memory film which is the core film of the memory cell. In various embodiments, examples of the material included in the memory layer 210 may include but are not limited to silicon oxide, aluminum oxide, germanium oxide, or transition metal oxide (e.g. HfOₓ, TaOₓ, CuOₓ, FeOₓ, WOₓ, ZrOₓ, TiOₓ, etc.), so as to form an anion-conducting based ReRAM cell. In various embodiments, the memory film 210 may include semiconductor materials (e.g. GeSe, GeS, CuTe, Si, Ge, etc.), so as to form an ion-conducting based ReRAM cell. In various embodiments, the memory film 210 may include chalcogenide materials (e.g. GST, AIST, etc.) or metal oxides (e.g. NiOₓ, CoOₓ, etc.), so as to form a PCRAM cell. The chalcogenide material refers to a material including chalcogen elements, wherein examples of chalcogen elements include oxygen (O), sulfur (S), selenium (Se), and tellurium (Te).

According to various embodiments, the third electrode layer 300, the selecting film 310 and the second electrode layer 220 of each lateral layer arrangement 250 form a selector for selecting a memory cell.

The selecting film 310 is the core film of the selector. In various embodiments, the selector may include at least one of an Ovonic Threshold Switch (OTS) selector or a Mott effect switch based selector. In various embodiments, the selecting film 310 may include chalcogenide materials (e.g. GST, SeTe, AsTeGeSiN, CuGeₓSe_{y}, doped-chalcogenide, etc.) so as to form an OTS selector. In various embodiments, the selecting film 310 may include Mott materials (e.g. NbOₓ, VOₓ, MoOₓ, etc.), so as to form a Mott effect switch based selector.

The second electrode layer 220 may include metals (Ta, Ti, W, Cu, Ag, Pt, Ir, TiN, TaN, etc.), or conductive oxide (ITO, Fe₃O₄, etc.).

According to various embodiments, the second electrode layer 220 is used as the electrodes of both the memory cell and the selector device, and may be referred to as an intermediate electrode layer. The second electrode layer 220 isolates the two critical films, i.e. the memory film 210 and the selecting film 310, to avoid the interaction of the materials in these two films. Because of the multiple role-play in the architecture, the second electrode layer 220 may include various or several materials, to satisfy different requirements from the memory cell, the selector, and the material isolation. In an exemplary embodiment, the second electrode layer 220 may include a Pt film and a Cu film. The Pt film may act as the electrode of the selector as well as the blocking film for Cu or other materials. The Cu film may act as the active electrode providing the copper ion in the ion-conducting based ReRAM cells. In another exemplary embodiment, the second electrode layer 220 may include TiN only. The TiN layer may act as the electrodes for both the anion-conducting based ReRAM, and OTS or Mott effect based selectors. Further, TiN may also act as a good blocking film to avoid materials intermixing.

According to various embodiments, the selecting film 310 may further include a plurality of lateral protruding portions 312. Each lateral protruding portion 312 is located within the respective lateral layer arrangement 250 and in contact with the second electrode layer 220 of the respective lateral layer arrangement 250, such that the lateral protruding portion 312 of the selecting film 310 is sandwiched between neighboring insulating layers 100 of the respective lateral layer arrangement 250. The lateral protruding portions 312 of the selecting film 310 may be used to clearly break the conducting path between electrodes 220 in different lateral layer arrangements 250. Although FIG. 1 shows an embodiment with lateral protruding portions 312, it is understood that the lateral protruding portions 312 may be optional. In other embodiments, the selecting film 310 may have a substantially flat lateral surface without protruding portions, which is in contact with the second electrode layers 220 and the insulating layers 100.

According to various embodiments, the memory device 10 may further include a further memory layer (not shown in FIG. 1) and a fourth electrode layer (not shown in FIG. 1) arranged at a further lateral side (e.g., the right side) opposite to the lateral side (e.g. the left side) of the first electrode layer 200 in each lateral layer arrangement 250. The further memory layer is sandwiched between the first electrode layer 200 and the fourth electrode layer. In other words, a plurality of memory cells are formed at the right side of the first electrode layers 200 similar to the memory cells formed at the left side of the first electrode layers 200 described above, so that a symmetric structure is formed. The first electrode layers 200 may thus be used as wordlines shared by the memory cells at the left side and at the right side of the first electrode layers 200.

The memory device 10 may further include a further selecting film (not shown in FIG. 1) arranged at a further lateral side (e.g. right side) opposite to the lateral side (e.g. left side) of the insulating layers 100 and the lateral layer arrangements 250, and extending in the direction 320 at least substantially perpendicular to the lateral direction 330 of the lateral layer arrangements 250. The further selecting film has a first surface in contact with the fourth electrode layer of each lateral layer arrangement 250. The memory device 10 may further include a fifth electrode layer (not shown in FIG. 1) arranged in contact with a second surface of the further selecting film opposite to the first surface of the further selecting film.

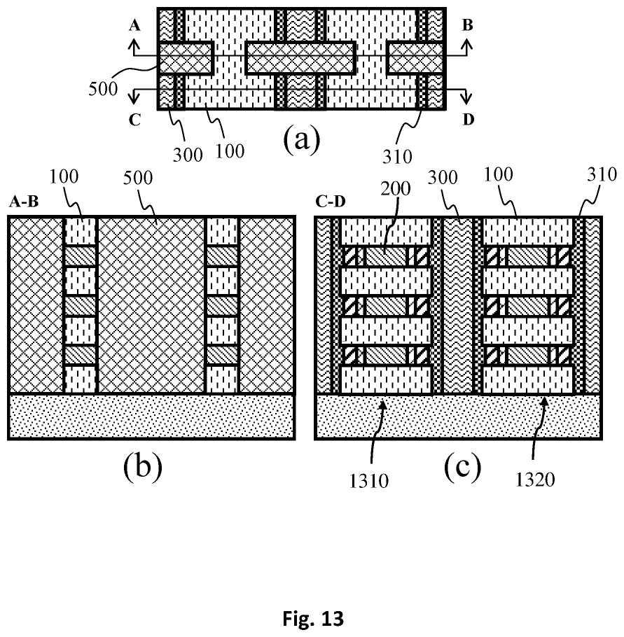

In other words, a plurality of selectors are formed at the right side of the first electrode layers 200 similar to the selectors formed at the left side of the first electrode layers 200 described above, so that a symmetric structure is formed. An exemplary embodiment of such a symmetric structure is illustrated as a memory stack 1310 or a memory stack 1320 shown in FIG. 13 below.

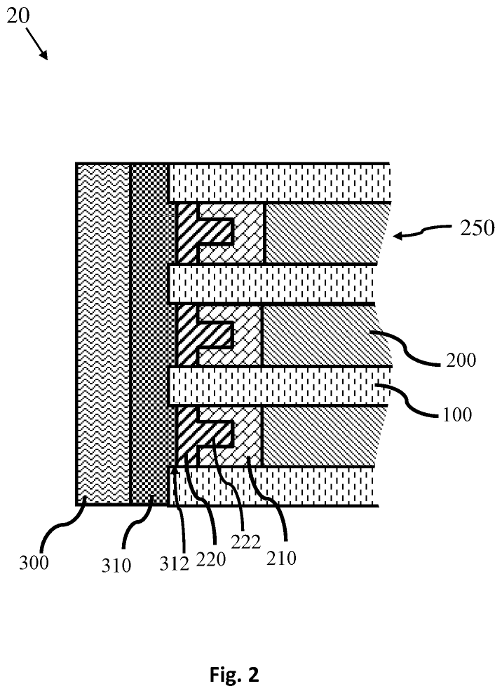

FIG. 2 shows a cross-sectional view of a memory device 20 according to various embodiments. The memory device 20 is similar to the memory device 10 above, includes the similar layers 100, 200, 210, 220, 300, 310 arranged in a similar manner. Various embodiments of the memory device 10 described above are analogously valid for the memory device 20, and vice versa.

According to the embodiments as shown in FIG. 2, in at least one of the lateral layer arrangements 250, the memory layer 210 may include a lateral groove and the second electrode layer 220 may include a lateral protrusion 222 fitting into the lateral groove. The lateral groove and the lateral protrusion 222 may be corresponding to or complementary to each other, such that the lateral protrusion 22 may fit into the lateral groove without any gap inbetween.

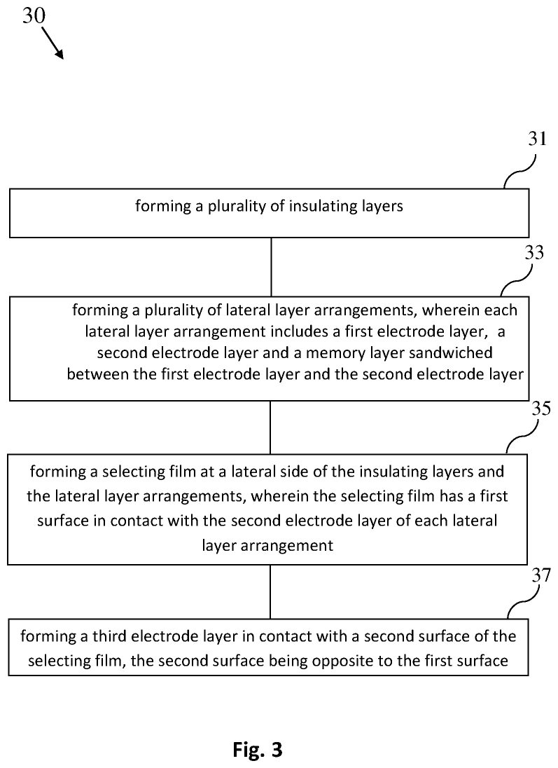

FIG. 3 shows a flowchart 30 illustrating a method of forming a memory device according to various embodiments. The method may be used to form the memory device 10 of FIG. 1 or the memory device 20 of FIG. 2 described above. Various embodiments of the memory device 10, 20 described above are analogously valid for the method, and vice versa.

At 31, a plurality of insulating layers is formed.

At 33, a plurality of lateral layer arrangements is formed, wherein the lateral layer arrangements and the insulating layers are arranged alternately on each other such that each lateral layer arrangement is sandwiched between neighboring insulating layers. Each lateral layer arrangement may include a first electrode layer; a second electrode layer; and a memory layer sandwiched between the first electrode layer and the second electrode layer, wherein the memory layer and the second electrode layer are arranged at a lateral side of the first electrode layer.

At 35, a selecting film is formed at a lateral side of the insulating layers and the lateral layer arrangements. The selecting film is extending in a direction at least substantially perpendicular to a lateral direction of the lateral layer arrangements, and the selecting film has a first surface in contact with the second electrode layer of each lateral layer arrangement.

At 37, a third electrode layer is formed in contact with a second surface of the selecting film, the second surface being opposite to the first surface.

It is understand that the processes or steps 31, 33, 35, 37 may not be carried out in sequence.

According to various embodiments, forming the plurality of lateral layer arrangements at 33 may further include forming the first electrode layers alternately on the insulating layers, such that each first electrode layer is sandwiched between neighboring insulating layers. A portion of each first electrode layer may be selectively etched to form a respective lateral recess. A respective memory layer is formed in the respective lateral recess; and a respective second electrode layer is formed next to the memory layer in the respective lateral recess.

According to various embodiments, forming the second electrode layer next to the memory layer in the respective lateral recess at 33 may further include forming a conductive layer conformally next to the memory layer and the insulating layers; and etching the conductive layer to expose the insulating layers and remove the conductive layer outside the respective lateral recess, thereby forming the second electrode layer next to the memory layer within the respective lateral recess.

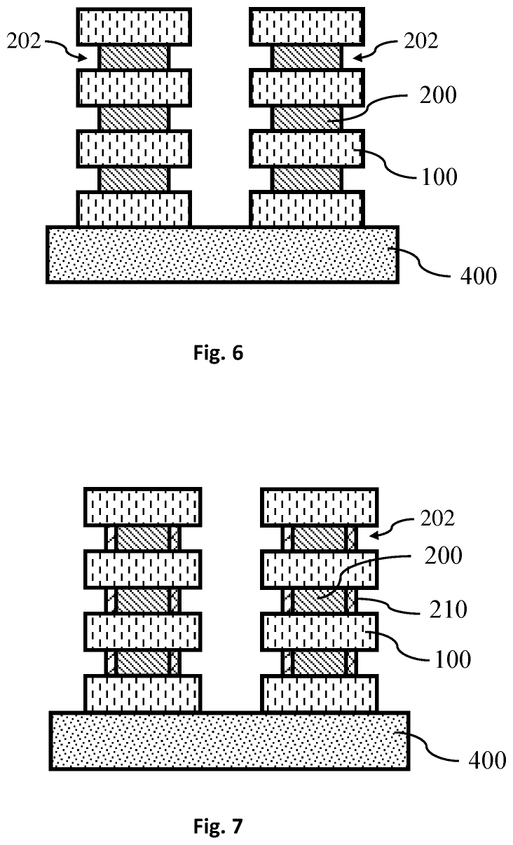

According to various embodiments, the portion of each first electrode layer may be selectively etched at 33 from the lateral side (e.g. the left side) and a further lateral side (e.g. the right side) of each first electrode layer to form the respective lateral recess at the lateral side and a respective lateral recess at the further lateral side, wherein the first lateral side is opposite to the second lateral side, for example, as shown in FIG. 6 below. The subsequent processes may be correspondingly carried out at the lateral side and the further lateral side of each first electrode layer, so as to form a symmetric structure of the memory device as described in the embodiments above.

According to various embodiments, the method 30 may further include forming a further memory layer and a fourth electrode layer at a further lateral side opposite to the lateral side of the first electrode layer in each lateral layer arrangement, wherein the further memory layer is sandwiched between the first electrode layer and the fourth electrode layer. The method 30 may further include forming a further selecting film at a further lateral side opposite to the lateral side of the insulating layers and the lateral layer arrangements. The further selecting film is extending in the direction at least substantially perpendicular to the lateral direction of the lateral layer arrangements, and the further selecting film has a first surface in contact with the fourth electrode layer of each lateral layer arrangement. The method 30 may further include forming a fifth electrode layer arranged in contact with a second surface of the further selecting film opposite to the first surface of the further selecting film.

According to various embodiments, the plurality of insulating layers and the plurality of first electrode layers may be etched at 33 to form a trench extending through the insulating layers and the first electrode layers, such that two stacks of layers separated by the trench are formed, as will be described in FIG. 5 below.

According to various embodiments, after forming the respective second electrode layer next to the memory layer in the respective lateral recess at 33, a portion of the respective second electrode may be etched to form a respective etch back portion, for example, the etch back portion 314 as shown in FIG. 9 below. The selecting film may be formed at 35 next to the second electrode layers and the insulating layers at the lateral side of the insulating layers and the second electrode layers, including the selecting film formed within the etch back portions to form a plurality of lateral protruding portions of the selecting film, e.g. the lateral protruding portions 312 of the selecting film shown in FIG. 1 above. Each lateral protruding portion of the selecting film is sandwiched between neighboring insulating layers. The forming of the etch back portions and the forming of the lateral protruding portions may be optional, and may be omitted in other embodiments.

According to various embodiments, in forming the lateral layer arrangement at 33, the memory layer may be formed in the respective lateral recess by conformal deposition, such that a lateral groove is formed in each memory layer. The second electrode layer may be formed at 33 next to the memory layer in the respective lateral recess, including forming a lateral protrusion of the second electrode layer fitting into the lateral groove, e.g., the lateral protrusion 222 of the second electrode layer as shown in FIG. 2 above.

According to various embodiments, each first electrode layer forms a wordline of the memory device. The third electrode layer forms a bitline of the memory device.

According to various embodiments, the respective first electrode layer, the respective memory layer and the respective second electrode layer form a respective memory cell. In various embodiments, the memory cell may include at least one of an ion-conducting based resistive random access memory, an anion-conducting based resistive random access memory, or a phase change memory.

According to various embodiments, the third electrode layer, the selecting film and the respective second electrode layer form a respective selector for selecting the respective memory cell.

According to various embodiments, the selecting film may include one of chalcogenide material or Mott material.

According to various embodiments above, a 3D memory architecture of the memory device is provided, including a multi-film stack including conductive layers and insulating layers alternatively arranged on each other. At the edge or lateral side of the stacking films, vertical memory cells (such as ReRAM or PCRAM cells) and vertical selectors are fabricated. The selectors are self-aligned to each memory cell to block the sneak current. Inbetween the memory film and selecting film, electrode materials are inserted to isolate these films.

According to various embodiments above, the neighboring insulating layers form a tunnel therebetween, inside which the memory layer 210 and the second electrode 220 of the selector is formed. This provides a 3D integration architecture that integrates memory cells and selectors together, and realizes 1S1R (one selector one resistor) scheme to eliminate the sneak paths.

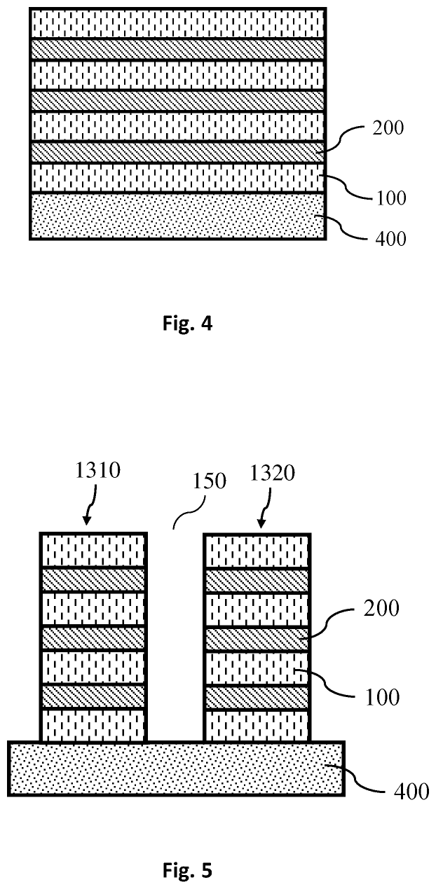

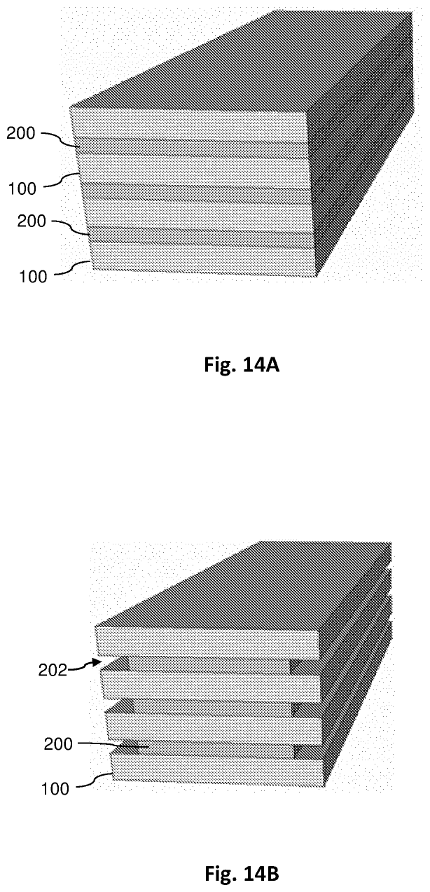

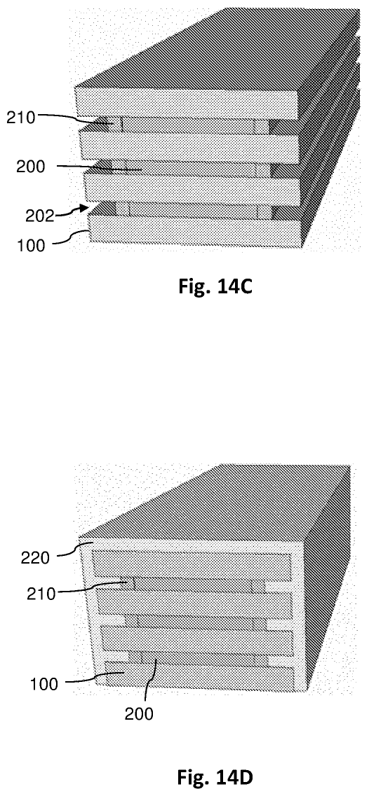

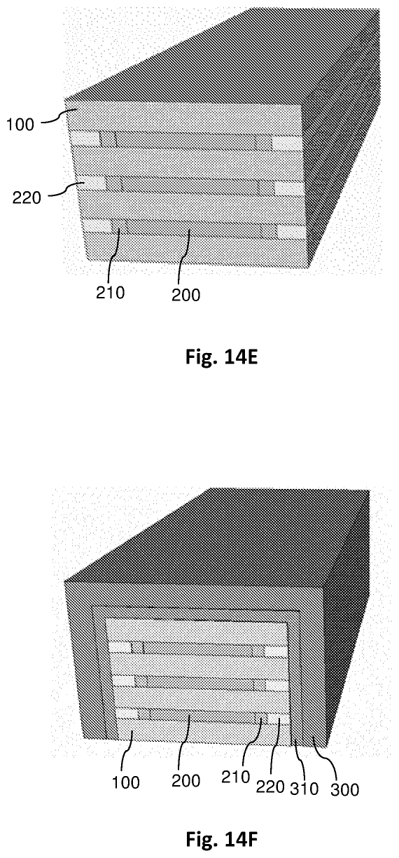

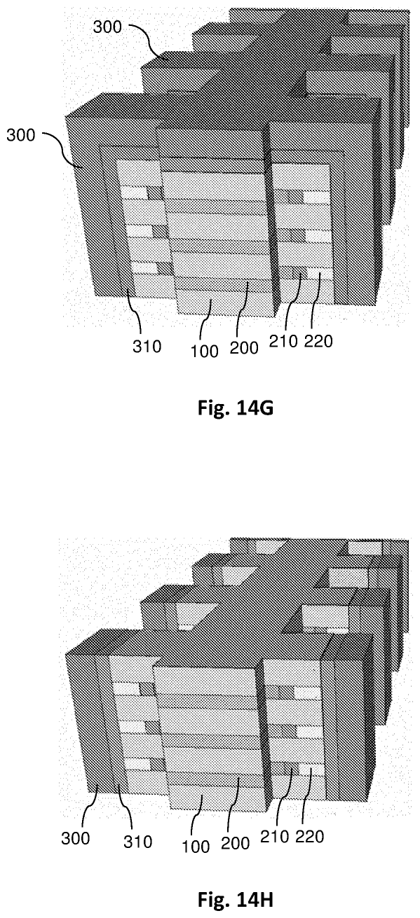

The method or process of forming the memory device according to various embodiments are described in more detail below in FIG. 4-FIG. 13, as well as FIGS. 14A-14H.

FIG. 4-FIG. 13 show a process of forming a memory device according to various embodiments. Various embodiments of the memory device 10, 20 and the method 30 described above are analogously valid for the process of FIG. 4-FIG. 13, and vice versa.

FIG. 4 shows an exemplary stack of layers to achieve the 3D memory array of various embodiments above. As shown in FIG. 4, the stack may include conductive layers 200 and insulating layers 100. The conductive layers 200 and the insulating layers 100 may be deposited alternately or alternatively, for example, using chemical vapor deposition method (CVD) or physical vapor deposition (PVD) method. The stack of layers 100, 200 may be fabricated on a substrate 400. The substrate 400 may act as the etching stop layer and isolation layer of devices below. The conductive layers 200 may be the first electrode layers 200 shown in FIG. 1 and FIG. 2 above.

In this exemplary embodiment, the insulating layer 100 may include silicon nitride, and the conductive layer 200 may include a tantalum thin film. In an embodiment, an extra mask layer may be optionally deposited on top of the stack layers (not shown in FIG. 4). This extra mask layer may act as a hard mask during the self-aligned etch-back in the latter processes. Furthermore, this extra mask layer may also act as an endpoint detection layer during CMP (Chemical mechanical polishing/planarization) processes.

FIG. 5 shows a side cross-sectional view of the stack of layers after etching according to various embodiments. The etching process may involve plasma dry etching to form the vertical profile. The selectivity of insulating layers 100 and conductive layers 200 may desire low selectivity between each other. After etching, two column stacks 1310, 1320 are formed by the trench 150 extending through the insulating layers 100 and the conductive layers 200. The column stacks include conductive layers 200 and insulating layers 100 running in a horizontal direction which is parallel to the silicon substrate 400, and may be also referred to as two memory stacks. The etching process stops on the substrate 400 which may provide etching end-point signal and low etching rate to improve the wafer-level etching uniformity. By the etching step in FIG. 5, two stacks of conductive layers 200 and insulating layers 100 are formed, such that each stack may be used to form memory cells and selectors, thereby increasing the density of the memory device. It is understood that the trench 150 of FIG. 5 may be optional according to other embodiments. For example, the stack may be etched only at the edge (e.g. the left edge and/or right edge), such that memory cells and selectors are formed using one stack only.

FIG. 6 shows a cross-sectional view of the stack of layers after a selective etching on the conductive layer according to various embodiments. As shown in FIG. 6, a respective lateral recess 202 is formed between neighboring insulating layers 100. The lateral recess 202 may be formed at either one or both lateral sides of the stacks. In order to achieve the high selectivity, a wet etch may be used. The wet etch may have a higher etching rate on the conductive layers 200, while a lower etching rate on the insulating layers 100.

In other embodiments, other assistant method might be used to assist the wet etching. In an exemplary embodiment, the conductive layers 200 may be tantalum films, and may be oxidized first by thermal anneal under oxygen ambient. Then a selective wet etching may include dilute hydrogen fluorine (DHF) to selectively etch the oxidized tantalum away, while leaving the tantalum metal thin film 200 and the silicon nitride film 100 less etched. This method may provide better control of etch-back uniformity and is also manufacture friendly.

FIG. 7 shows a cross-sectional view of the stack of layers after a memory layer formation according to various embodiments. Several methods may be used to form the memory layer 210. The memory layer 210 may be a few nanometers thick. The simplest formation of the memory layer 210 may be performed by thermal oxidation of metal electrode in the embodiments wherein the oxidized metal acts as the memory layer. In an exemplary embodiment, a memory layer of tantalum oxide 210 may be formed by oxidation of tantalum electrode in low temperature under the oxygen ambient. In alternative embodiments, the memory layer 210 may be formed by selective deposition of metal oxide, or by a non-selective deposition leaving a continuous film.

In various embodiments, the non-selective deposition may be carried out via an atomic layer deposition (ALD) method. The memory layer 210 may be formed by conformal deposition, e.g. via ALD, such that the memory layers are confined inside the stack tunnel. After ALD deposition, an etch-back of ALD film may be required under the self-aligned dry etching. The cross-sectional view of the memory stack using ALD deposition and etch-back to form the memory layer 210 is shown in the embodiments of FIG. 2, e.g. the memory layer 210 with the shape of a lateral groove as shown in FIG. 2.

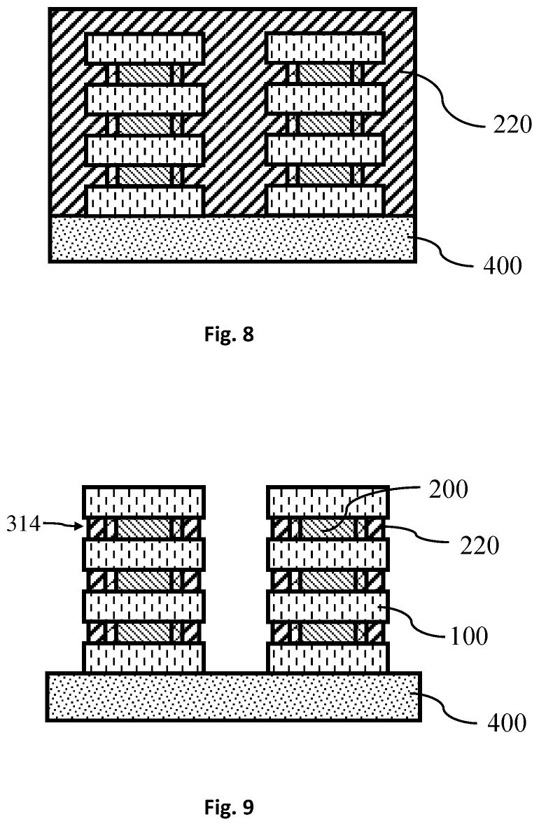

FIG. 8 shows a cross-sectional view of the memory stack after intermediate electrode layer deposition according to various embodiments. The intermediate electrode layer 220, i.e. the second electrode layer 220, is formed next to the respective memory layer 210 in the respective lateral recess 202.

In an exemplary embodiment, the deposition of the intermediate electrode layer 220 may be achieved by the ALD deposition method in order to achieve the conformal conductive film inside the etch-back tunnel, i.e. the lateral recess 202. In one illustrative example, the conductive film of titanium nitride (TiN) 220 may be deposited using ALD method. The ALD growth of titanium nitride is mature in current semiconductor industry. Titanium tetrachloride (TiC1₄), tetrakis (dimethylamino) titanium (TDMAT) or other titanium precursor may be used together with N₂ or NH₃ to deposit TiN in a plasma enhance atomic layer deposition (PEALD) system. In another illustrative example, a conductive film of platinum 220 may be deposited using ALD or PEALD method as well.

In another exemplary embodiment, electroplating process may be used to deposit the metal conductive film 220, which may include copper, silver, platinum and other suitable materials. The electroplating process can also provide good step coverage filling in deep trenches or tunnels.

According to an exemplary embodiment as shown in FIG. 8, the conductive layer 220 is formed conformally next to the memory layer 210 and the insulating layers 100 and on the top insulating layer 100. The conductive layer 220 may also be formed in the trench 150 covering the entire stacks. The conformal conductive layer 220 may be etched in the next step of FIG. 9 to remove the conductive layer next to the insulating layers 100 and on the top insulating layer, i.e. to expose the insulating layers 100 and to remove the conductive layer 220 outside the respective lateral recess, thereby forming the second electrode layer 220 in the respective lateral recess 202 as shown in FIG. 9.

FIG. 9 shows a cross-sectional view of the memory stack after the etch-back of the intermediate electrode layer 200 of FIG. 8 according to various embodiments. After the conformal deposition of intermediate electrode layer 220, a self-align etch-back process may be performed to etch the excessive conductive material away outside the tunnel, while less etching on the insulating layer 110 or the substrate film 400. The etch-back process may include dry plasma etch, or wet chemical etch, or a mixture of both etches, because some conductive materials 220, e.g. some metals might be difficult to be etched away.

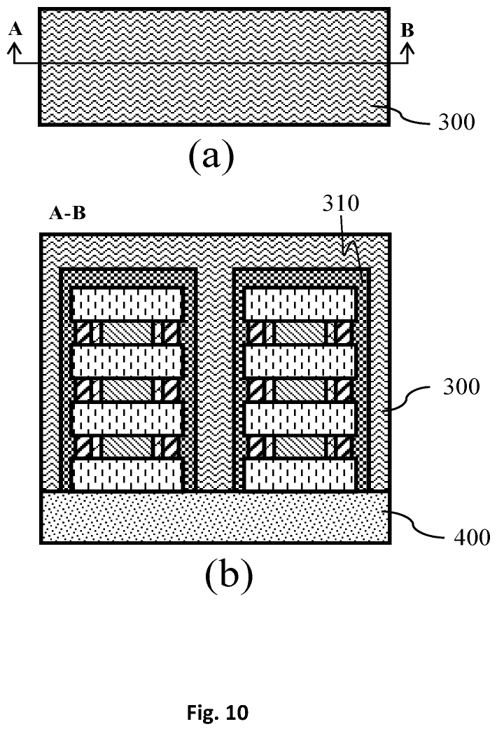

In various embodiments a slightly etch-back inside the tunnel or the lateral recess 202 may be carried out to form the respective etch back portion 314, in order to clearly break the conducting path between electrodes in different layers. The selecting film may be subsequently formed to fill in the respective etch back portion 314 as illustrated in FIG. 10 below, so as to form the plurality of protruding portions 312 of the selecting film 310 as shown in FIG. 1 above. Herein, the second electrode layer 220, the memory layer 210 and the first electrode layer 200 are combined to form the respective memory cell.

FIG. 10 shows the memory stack after the deposition of the selecting film and an outer electrode layer according to various embodiments. FIG. 10(a) shows the top view of the memory stack. FIG. 10(b) shows the cross-sectional view of the memory stack along the A-B plane of FIG. 10(a).

The selecting film 310 may be first deposited by either CVD or PVD method. The selecting film 310 is an insulating film without external stresses, and becomes conductive under an external voltage or thermal heat. The selecting film 310 may include chalcogenide materials (e.g. GST, SeTe, AsTeGeSiN, CuGeₓSe_{y}, doped-chalcogenide, etc.), or Mott materials (e.g. NbOₓ, VOₓ, MoOₓ, etc.). The selecting film 310 may be formed next to the second electrode layers 220 and the insulating layers 100 at either one or both lateral sides of the second electrode layers 220 and the insulating layers 100. The selecting film 310 may also be formed to cover the stack of layers as shown in FIG. 10(b).

After the deposition of the selecting film 310, the outer electrode layer 300, i.e.

the third electrode layer 300, may be deposited next to the selecting film 310 at the lateral side of the selecting film 310, and may be deposited further on top of the selecting film 310 and between the stacks as shown in FIG. 10. Herein, the third electrode layer 300, the selecting layer 310 and the second electrode layer 220 are combined together to form a respective selector device.

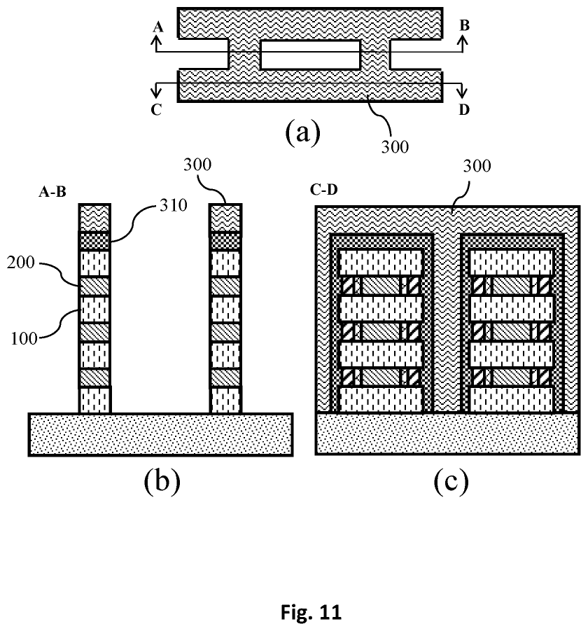

FIG. 11 shows the memory stack after an isolating-etch according to various embodiments. FIG. 11(a) shows a top view of the memory stack. FIG. 11(b) shows a cross sectional view along the A-B plane of FIG. 11(a), and FIG. 11(c) show a cross-sectional view along the C-D plane of FIG. 11(a).

After the isolating etching, the memory cell and selectors may be isolated from the neighboring memory cells or selectors in a horizontal direction, and leave the conductive line 200 unbroken. During the etching, different materials including the memory layer 210, the intermediate electrode layer 220, the selecting film 310, the outer electrode layer 300, and part of the insulating film 100 and the conductive film 200 may be etched way at the same time. Thus, a non-selective dry etching may be used which may include a mixture of Argon bombardment etches (Ar) and chemical dry etches for both oxides and metals (CF₄/C1₂).

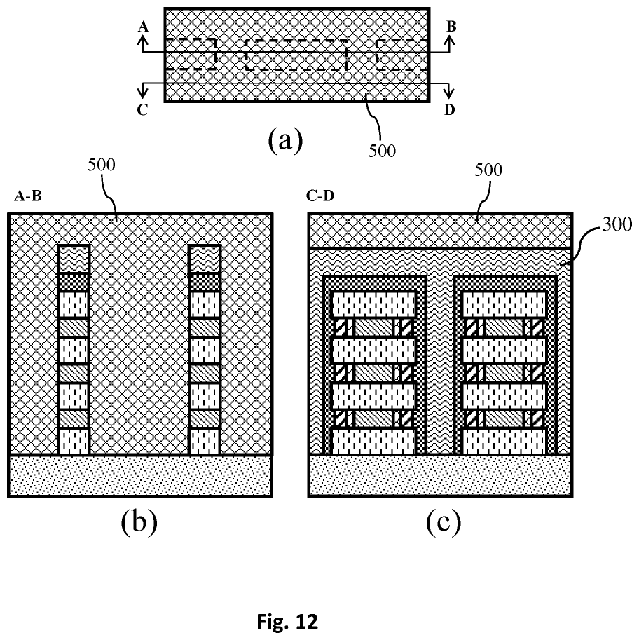

FIG. 12 shows the memory stack after a dielectric film formation according to various embodiments. FIG. 12(a) shows a top view of the memory stack. FIG. 12(b) shows a cross-sectional view along the A-B plane of FIG. 12(a), and FIG. 12(c) show a cross-sectional view along the C-D plane of FIG. 12(a). After isolation etching of FIG. 11, a dielectric film 500 filling may be performed to the etched trenches. In an exemplary embodiment, the dielectric film 500 of SiO₂ may be deposited by ALD method. A high quality thin film ALD Al₂O₃ may be inserted before SiO₂ filling for better isolation.

FIG. 13 show the memory stack after the Chemical Mechanical Planarization (CMP) process according to various embodiments. FIG. 13(a) shows a top view of the memory stack. FIG. 13(b) shows a cross-sectional view along the A-B plane of FIG. 13(a), and FIG. 13(c) shows a cross-sectional view along the C-D plane of FIG. 13(a). The main purpose of the CMP process is to isolate bitline columns, i.e., the third electrode layer 300, from each other, so as to achieve that only one memory cell is addressed each time during the memory operation. Hence, the upper part films of FIG. 12, including the dielectric filling 500, the top part of the outer electrode 300 and the selecting film 310, may be polished away. The end of CMP process may be determined by the extra mask layer signal mentioned in FIG. 4 above.

Accordingly, through the process of FIG. 4 to FIG. 13 above, a memory device including a 3D array of memory cells along with selectors according to various embodiments is formed. In the illustrative example of FIG. 13(c), multiple layers of memory cells have been formed, shown in two memory stacks 1310, 1320 sharing the same bitline 300. Each memory stack may also include two layers of memory cells sharing the same wordline 200. It is also understood that only one memory stack may be formed according to the process of various embodiments above, for example, without forming the trench 105 in FIG. 5 above.

The memory device 10, 20 formed according to the method 30 and the process of FIG. 4-FIG. 13 above includes memory cells formed inside the tunnel sandwiched between neighboring insulating layers. In other words, the memory layers 210 are formed within the lateral layer arrangements 250. The vertical selectors are formed, with the second electrode 220 of the selectors also formed within the tunnel. Further, the memory material of the memory device 20 of FIG. 2 may be deposited by ALD as described above so as to optionally form the lateral protruding portions 222 of the second electrode layers 220. By forming the memory cells or at least part of selectors inside the tunnel, 1S1R operation scheme may be achieved. According to the memory devices 10, 20 of various embodiments above, leakage current can be greatly reduced. Accordingly, various embodiments enables truly 3D integration of vertical memory array (e.g. ReRAM array) with reduced leakage current and less operation errors.

FIG. 14A-FIG. 14H show a process of forming a memory device in 3D view according to various embodiments. Various embodiments of the memory device 10, 20, the method 30 and the process of FIG. 4-FIG. 13 described above are analogously valid for the process of FIG. 14A-FIG. 14H, and vice versa.

As shown in FIG. 14A, multilayer deposition may be carried out to form a multilayer stack. The multilayer stack includes insulating layers 100 and conductive layers 200 arranged alternately on each other. The insulating layers 100 may be SiN layers, and the conductive layers 200 may be Ta layers or Ti layers.

In FIG. 14B, the conductive layers 200 are etched back to form the respective lateral recess 202. The etching back is performed at both lateral sides of the conductive layers 200 in the embodiments shown in FIG. 14B, and may also be performed at only one lateral side of the conductive layers 200 in other embodiments.

In FIG. 14C, a respective switching material, i.e. the memory layer 210, is formed in the respective lateral recess 202.

In FIG. 14D, a second conductive layer 220, e.g. metal electrode, is deposited over the multilayer stack. The second conductive layer 220 may be formed next to the memory layer 210 to fill in the lateral recess 202.

In FIG. 14E, a self-align etch back is carried out to etch excessive second conductive layer 220 so as to form the second electrode layer 220 only within the respective lateral recess. The conductive layer 200, the memory layer 210 and the second electrode layer 220 form the lateral layer arrangement 250 of FIG. 1, and also form the memory cell within the tunnel sandwiched between neighboring insulating layers 100.

In FIG. 14F, a selecting film 310 is deposited next to the second electrode layers 220 and the insulating layers 100 at the lateral side of the insulating layers 10 and the second electrode layers 220. The selecting film 310 may be formed to cover the entire stack layers as shown in FIG. 14F. In this embodiment, the selecting film 310 is formed without any lateral protruding portions (e.g. lateral protruding portion 312 shown in FIG. 1). A third electrode layer 300 is further deposited next to the selecting film 310 at the lateral side of the selecting film 310, and may further be formed over the top selector film 310 as shown in FIG. 14F.

In FIG. 14G, a column etch is carried out to form a 1S1R architecture, such that the third electrode layers 300 are separated to form respective bitlines separated from each other.

In FIG. 14H, individual memory columns (e.g. RRAM columns) are formed by a CMP process, in which the top layers of the third electrode layer 300 and of the selecting film 310 are removed.

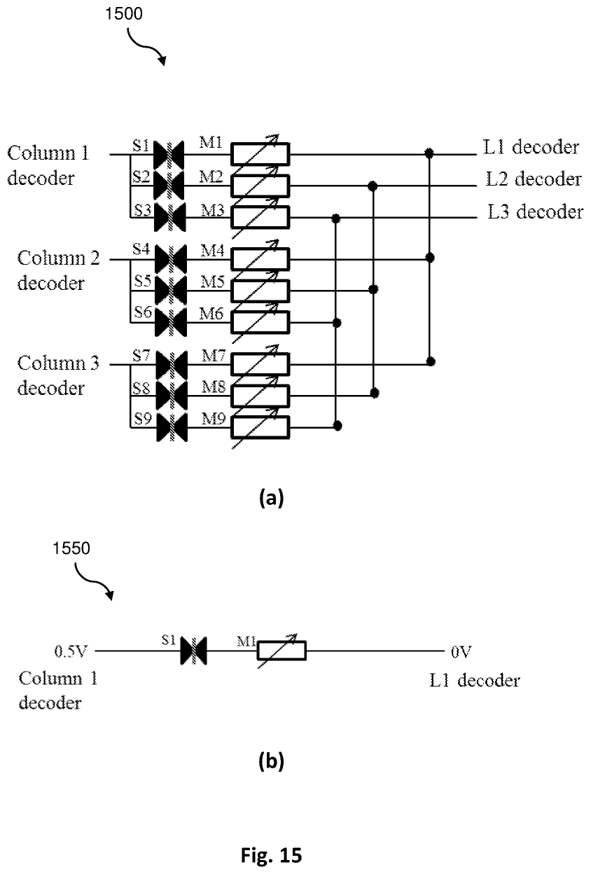

FIG. 15(a) shows an equivalent circuit 1500 illustrating leakage current calculation for a memory device (e.g. memory device 10, 20) according to various embodiments.

As shown in FIG. 15(a), each memory cell as denoted by Mᵢ is provided with a selector Si. In this illustrative embodiment, the memory device includes 9 memory cells (M1-M9) and 9 selectors (S1-S9). The column decoders (e.g., column 1 decoder, column 2 decoder and column 3 decoder) and the layer decoders (e.g., L1 decoder, L2 decoder and L3 decoder) may be used to select the respective memory cell. The leakage current Iₗₑₐₖ may be calculated according to the following equation:

Iₗₑₐₖ=((M−1)+(N−1)+(H−1))*I_{(selector off current)}

M represents the number of wordlines, N represents the number of bitlines, and H represents the number of layers. I_{(selector off current)} represents the current when the selector is off.

TABLE 1

| | | | |
|---|---|---|---|
| column 1 decoder | 0.5 V | L1 decoder | 0 V |
| column 2 decoder | floating | L2 decoder | floating |
| column 3 decoder | floating | L3 decoder | floating |

Table 1 shows the voltage setting when reading the memory cell M1. An equivalent circuit 1550 when reading the memory cell M1 is shown in FIG. 15(b), which shows that no current sneak path exists to disturb the memory reading according to the memory device of various embodiments. The current sneak path is eliminated by the discontinuous intermediate electrode layer 220 according to various embodiments, in which each intermediate electrode layer 220 is confined with the tunnel of each lateral layer arrangement 250.

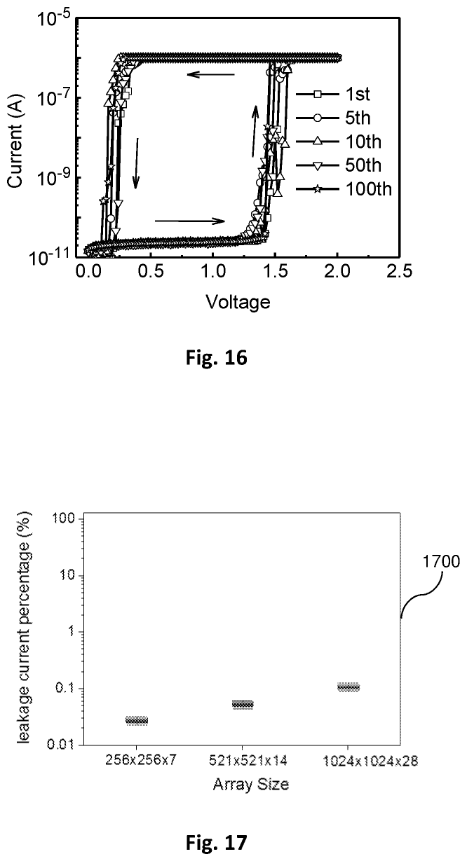

FIG. 16 shows a current-voltage curve for a selector according to various embodiments.

The selector may be a selector device described in WO2016/122406A1, wherein the selecting film of the selector device includes at least one metal rich layer and at least one chalcogenide rich layer. This selecting film may be used as the selecting film 310 of the memory device 10, 20 above.

The metal rich layer may include at least one of a metal or a metal compound. The metal rich layer refers to a layer including metal elements, in which the metal content is greater than 50 at. % (atomic percentage) so that the metal elements are the majority elements in the metal rich layer.

The chalcogenide rich layer refers to a layer of chalcogenide, or a layer of mixture including chalcogenide, in which the chalcogenide content is greater than 50 at. % so that the chalcogenides are the majority compounds in the chalcogenide rich layer. In various embodiments, the chalcogenide rich layer may include a mixture of chalcogenide and other dielectric or metal materials, in which the chalcogenide content is greater than 50 at. %, higher than the other dielectric or metal content. Examples of dielectric or metal material that may be included in the chalcogenide rich layer may include but are not limited to Al₂O₃, SiO₂, Si₃N₄, Ag, Cu, and Zn. A chalcogenide includes chalcogen elements, wherein examples of chalcogen elements include oxygen (O), sulfur (S), selenium (Se), and tellurium (Te). The metal rich layer and the chalcogenide rich layer may have different materials, different element composition, or different atomic percentages of various element components. In other words, the material composition or the element composition of the metal rich layer is different from that of the chalcogenide rich layer 314.

FIG. 16 shows the current-voltage curves for 100 cycle of the selector having the selecting film described above. At the voltage of 0.8V, the selector off current I_{(selector off current)} is about 1 E-4 μA. The selector shows sharp transition at the threshold voltage around 1.5V, and can hold the high current when the supplied voltage is above the holding voltage around 0.2V. The on-states of the selector device can be hold until the voltage drops below the holding voltage of 0.2V during the backward sweeping.

FIG. 17 shows a diagram 1700 illustrating a leakage current percentage of a memory device (e.g., memory device 10) according to various embodiments.

In FIG. 17, simulation results for the memory devices of various array sizes is shown. In this example, memory devices of 256×256×7, 521×521×14, and 1024×1024×28 are tested. For example, in the array size of 1024×1024×28, 1024 represents the number of wordlines, 1024 represents the number of bitlines, and 28 represents the number of layers.

The leakage current percentage is calculated according to the following equation:

$$\frac{{I}_{leak}}{{I}_{total}} = \frac{{I}_{leak}}{{I}_{selected cell} + {I}_{leak}}$$

As shown in the results of FIG. 17, very low leakage current percentage has been achieved by the memory device according to various embodiments.

By using the memory device structure (e.g. as in FIG. 1) of various embodiments including selectors of FIG. 16 above and RRAM memory cells, the leakage current may be significantly reduced for more than three orders compared with existing memory device structures. The waste energy during SET operation in the memory array can also be greatly reduced to 1% by using the memory device of various embodiments.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A memory device, comprising:
a plurality of insulating layers;
a plurality of lateral layer arrangements, wherein the lateral layer arrangements and the insulating layers are arranged alternately on each other such that each lateral layer arrangement is sandwiched between neighboring insulating layers, wherein each lateral layer arrangement comprises:
a first electrode layer;
a second electrode layer; and
a memory layer sandwiched between the first electrode layer and the second electrode layer, wherein the memory layer and the second electrode layer are arranged at a lateral side of the first electrode layer;
a selecting film arranged at a lateral side of the insulating layers and the lateral layer arrangements and extending in a direction at least substantially perpendicular to a lateral direction of the lateral layer arrangements, wherein the selecting film has a first surface in contact with the second electrode layer of each lateral layer arrangement; and
a third electrode layer arranged in contact with a second surface of the selecting film, the second surface being opposite to the first surface.

2. The memory device according to claim 1,
wherein the first electrode layer of each lateral layer arrangement forms a wordline of the memory device;
wherein the third electrode layer forms a bitline of the memory device.

3. The memory device according to claim 1,
wherein the first electrode layer, the memory layer and the second electrode layer of each lateral layer arrangement form a memory cell.

4. The memory device according to claim 3,
wherein the memory cell comprises at least one of an ion-conducting based resistive random access memory, an anion-conducting based resistive random access memory, or a phase change memory.

5. The memory device according to claim 1,
wherein the third electrode layer, the selecting film and the second electrode layer of each lateral layer arrangement form a selector for selecting a memory cell.

6. The memory device according to claim 1,
wherein the selecting film comprises one of chalcogenide material or Mott material.

7. The memory device according to claim 1,
wherein the selecting film further comprises a plurality of lateral protruding portions,
wherein each lateral protruding portion is located within the respective lateral layer arrangement and in contact with the second electrode layer of the respective lateral layer arrangement, such that the lateral protruding portion of the selecting film is sandwiched between neighboring insulating layers of the respective lateral layer arrangement.

8. The memory device according to claim 1,
wherein in at least one of the lateral layer arrangements, the memory layer comprises a lateral groove and the second electrode layer comprises a lateral protrusion fitting into the lateral groove.

9. The memory device according to claim 1, further comprising:
a further memory layer and a fourth electrode layer arranged at a further lateral side opposite to the lateral side of the first electrode layer in each lateral layer arrangement, wherein the further memory layer is sandwiched between the first electrode layer and the fourth electrode layer;
a further selecting film arranged at a further lateral side opposite to the lateral side of the insulating layers and the lateral layer arrangements, and extending in the direction at least substantially perpendicular to the lateral direction of the lateral layer arrangements, wherein the further selecting film has a first surface in contact with the fourth electrode layer of each lateral layer arrangement; and
a fifth electrode layer arranged in contact with a second surface of the further selecting film opposite to the first surface of the further selecting film.

10. A method of forming a memory device, the method comprising:
forming a plurality of insulating layers;
forming a plurality of lateral layer arrangements, wherein the lateral layer arrangements and the insulating layers are arranged alternately on each other such that each lateral layer arrangement is sandwiched between neighboring insulating layers,
wherein each lateral layer arrangement comprises:
a first electrode layer;
a second electrode layer; and
a memory layer sandwiched between the first electrode layer and the second electrode layer, wherein the memory layer and the second electrode layer are arranged at a lateral side of the first electrode layer;
forming a selecting film at a lateral side of the insulating layers and the lateral layer arrangements, wherein the selecting film is extending in a direction at least substantially perpendicular to a lateral direction of the lateral layer arrangements,
wherein the selecting film has a first surface in contact with the second electrode layer of each lateral layer arrangement; and
forming a third electrode layer in contact with a second surface of the selecting film, the second surface being opposite to the first surface.

11. The method according to claim 10, wherein forming the plurality of lateral layer arrangements further comprises:
forming the first electrode layers alternately on the insulating layers, such that each first electrode layer is sandwiched between neighboring insulating layers;
selectively etching a portion of each first electrode layer to form a respective lateral recess;
forming a respective memory layer in the respective lateral recess; and
forming a respective second electrode layer next to the memory layer in the respective lateral recess.

12. The method according to claim 11, wherein forming the second electrode layer next to the memory layer in the respective lateral recess further comprises:
forming a conductive layer conformally next to the memory layer and the insulating layers; and
etching the conductive layer to expose the insulating layers and remove the conductive layer outside the respective lateral recess, thereby forming the second electrode layer next to the memory layer within the respective lateral recess.

13. The method according to claim 11, further comprising:
selectively etching the portion of each first electrode layer from the lateral side and a further lateral side of each first electrode layer to form the respective lateral recess at the lateral side and a respective lateral recess at the further lateral side, wherein the lateral side is opposite to the further lateral side.

14. The method according to claim 11, further comprising:
etching the plurality of insulating layers and the plurality of first electrode layers to form a trench extending through the insulating layers and the first electrode layers, such that two stacks of layers separated by the trench are formed.

15. The method according to claim 10, further comprising:
etching a portion of the respective second electrode layer to form a respective etch back portion, and
forming the selecting film next to the second electrode layers and the insulating layers at the lateral side of the insulating layers and the second electrode layers, including forming the selecting film within the etch back portions to form a plurality of lateral protruding portions of the selecting film, wherein each lateral protruding portion of the selecting film is sandwiched between neighboring insulating layers.

16. The method according to claim 10, wherein forming the lateral layer arrangements further comprises:
forming the memory layer by conformal deposition, such that a lateral groove is formed in each memory layer; and
forming the second electrode layer next to the memory layer, including forming a lateral protrusion of the second electrode layer fitting into the lateral groove.

17. The method according to claim 10, further comprising:
forming a further memory layer and a fourth electrode layer at a further lateral side opposite to the lateral side of the first electrode layer in each lateral layer arrangement, wherein the further memory layer is sandwiched between the first electrode layer and the fourth electrode layer;
forming a further selecting film at a further lateral side opposite to the lateral side of the insulating layers and the lateral layer arrangements, wherein the further selecting film is extending in the direction at least substantially perpendicular to the lateral direction of the lateral layer arrangements, wherein the further selecting film has a first surface in contact with the fourth electrode layer of each lateral layer arrangement; and
forming a fifth electrode layer arranged in contact with a second surface of the further selecting film opposite to the first surface of the further selecting film.

18. The method according to claim 10,
wherein each first electrode layer forms a wordline of the memory device,
wherein the third electrode layer forms a bitline of the memory device.

19. The method according to claim 10,
wherein the respective first electrode layer, the respective memory layer and the respective second electrode layer form a respective memory cell.

20. The method according to claim 10,
wherein the third electrode layer, the selecting film and the respective second electrode layer form a respective selector for selecting the respective memory cell.
